(19) United States
(12) Patent Application Publication
(10) Pub. No.: US 2008/0156464 A1
(43) Pub. Date: Jul. 3, 2008

(54) Heat pipe structure with sectional heat conducting capability

(75) Inventors: Tung-Hsing Tsou, Hsinchu County (TW); Cheng-Kang Wen, Hsinchu County (TW); Chang-Lung Li, Hsinchu County (TW)

Correspondence Address: Joe McKinney Muncy, PO Box 1364, Fairfax, VA, 22038-1364, US

(73) Assignee: CHENG HOME ELECTRONICS CO., LTD.

(21) Appl. No.: 11/645,720

(22) Filed: Dec. 27, 2006

(51) Int. Cl. H05K 7/20

(52) U.S. Cl. 165/104.33; 361/700

(57) ABSTRACT

A heat pipe structure with sectional heat conducting capability includes a hollow metal pipe and a working liquid, in the hollow metal pipe, having a heat absorption/exothermic cycle for achieving a heat dispersing effect. In the present invention, at least one pressed section is located between the ends of the metal pipe, and the pressed section further has, relative to the pipe, an indentation portion to contact with the sidewall of the metal pipe so as to form a sealing surface on the metal pipe such the metal pipe is divided into at least two sections which respectively have a heat absorption/exothermic cycle. Therefore, except improving the arrangement flexibility and heat dispersing effect, the processing procedure can be simplified and the cost also can be reduced.

### FIELD OF THE INVENTION

The present invention is related to a heat pipe, and more particularly to a heat pipe structure with sectional heat conducting capability.

### BACKGROUND OF THE INVENTION

With the dramatic development of 3C technical industry, the 3C products are continuously upgraded and progressed, especially in efficiency. However, the problem of heat dispersing is also derived from the efficiency improvement since most electronic products employ the heat dispersing module to exhaust the heat inside the product.

Take computer as an example. If the heat generated from the electronic components can not be exhausted, then the gradually increased inner temperature causes the computer to have a crush or out of function. Therefore, the personal computer is generally equipped with heat sink and heat fan. Heat sink has numerous metallic fins at one surface thereof which benefit the reduction of computer temperature, that is, the principle of heat sink is to increase the heat dispersing areas, and then, the heat can be blown away through the airflow therearound which is always generated by the fan. However, because the heat-dispersing efficiency of the heat sink is inefficient, an advanced heat-dispersing technology-heat pipe is developed.

Heat pipe is a sealed metal pipe which contains a proper amount of working liquid, such as, pure water or acetone. When one end (heat exposing end) of the heat pipe suffers the heat, the working liquid at this end will be vaporized to generate a vapor pressure since the working liquid is under a vacuum state. Then, owing to the pressure, the vapor moves to the other end (the cooling end), which has a lower pressure, and once again condenses into liquid and releases the latent heat of condensation. Finally, after condensation, the working liquid returns to the heat exposing end due to capillarity. Consequently, the constant repeat of vaporization and condensation achieves the purpose of heat transfer.

Please refer to R.O.C Patent No. I250913. Conventionally, the heat pipe is a hollow metal pipe employing the heat absorption/exothermic cycle of a working liquid thereinside to achieve heat dispersing. However, for the inner system of computer, it will be preferable that each high temperature heat source is paired with a heat pipe, for example, the Southbridge and Northbridge chipsets on the mother board, or the CPU (central processing unit) should respectively have different heat pipe. However, not only the cost thereof must be significantly increased, but the space in the computer might also be insufficient since a lot of heat pipes will be occupied so as to limit the arrangement of other electronic elements thereinside.

### SUMMARY OF THE INVENTION

The object of the present invention is to provide a heat pipe structure with sectional heat conducting capability which can provide at least two sections of heat dispersing cycles for accelerating the backflow of the working liquid so that the arranging flexibility of the heat pipe and the heat dispersing effect both can be improved, the processing procedure can be simplified and the cost also can be reduced.

For achieving the object described above, the technical content disclosed by present invention includes a hollow metal pipe and a working liquid, in the hollow metal pipe, having a heat absorption/exothermic cycle for achieving a heat dispersing effect. In the present invention, at least one pressed section is located between the ends of the metal pipe, and the pressed section further has, relative to the pipe, an indentation portion to contact with the sidewall of the metal pipe so as to form a sealing surface on the metal pipe such the metal pipe is divided into at least two sections which respectively have a heat absorption/exothermic cycle.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a structural drawing of a preferred embodiment in the present invention;

FIG. 2 is a sectional drawing of a preferred embodiment in the present invention; and

FIG. 3 is a configuration drawing of a preferred embodiment in the present invention.

### DESCRIPTION OF THE PREFERRED EMBODIMENT

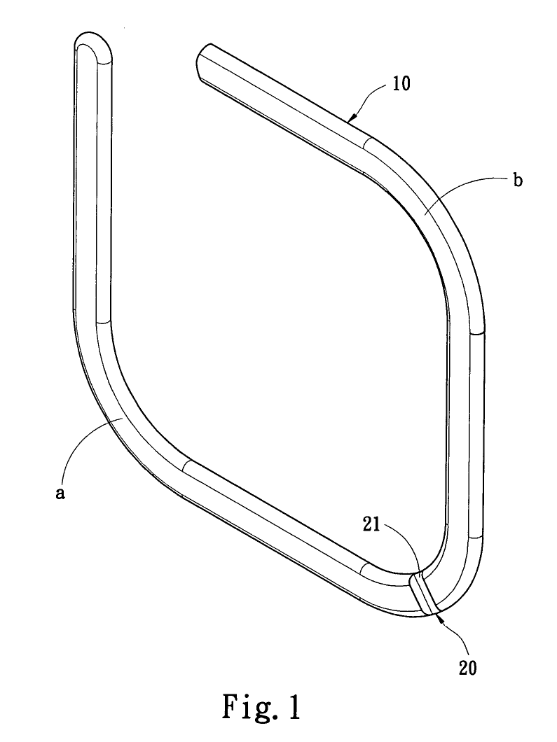

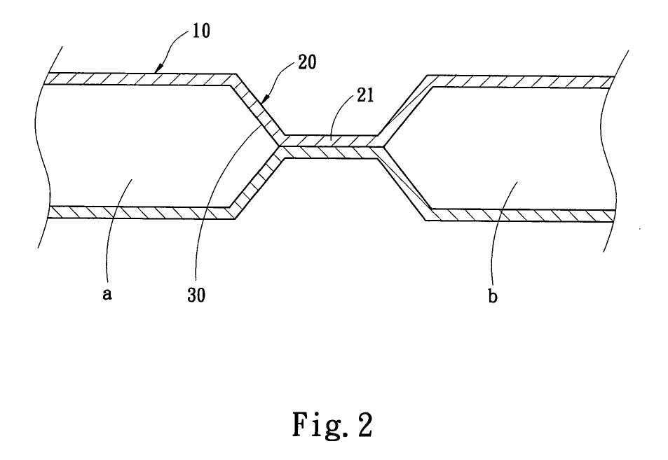

Please refer to FIG. 1, which is the structural drawing of a preferred embodiment in the present invention. As shown, a heat pipe structure with sectional heat conducting capability according to the present invention includes a hollow metal pipe 10 (such as capper pipe), and through the heat absorption/exothermic cycle of the working liquid in the metal pipe 10, a heat dispersing effect can be achieved. The present invention is characterized in that, between the end portions of the metal pipe 10, at least one pressed section 20 is located, and the pressed section 20 has an indentation portion 21 relative to the metal pipe 10, wherein the indentation portion 21 is contacted with the inner sidewall of the metal pipe (as shown in FIG. 2), or there are two indentation portions 21 at a corresponding position to contact together, so as to construct a sealing surface 30 on the metal pipe 10, so that the metal pipe 10 is divided into a first section a and a second section b, which can respectively proceed the absorption/exothermic cycle, by the indentation portion 21.

The sectional area of the metal pipe 10 can be a rectangular, or it can be a circle or other shapes. Besides, according to the present invention, for matching the position or structure of the heat source, the metal pipe 10 can be a bar pipe or can have at least one bending point to become a bent pipe.

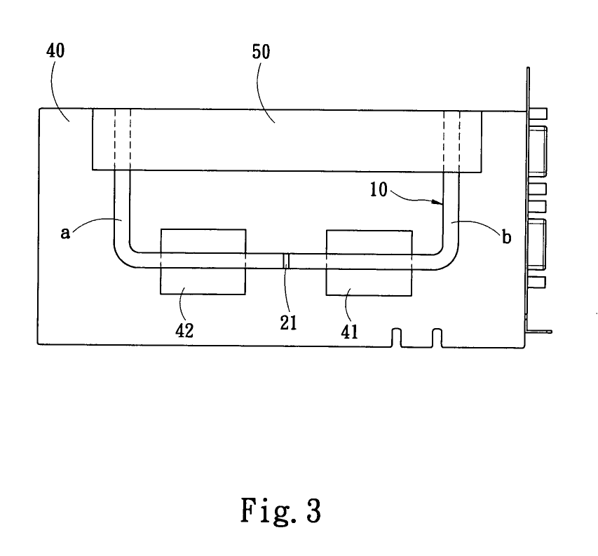

Please refer to FIG. 3, which is a configuration drawing of a preferred embodiment according to the present invention. As shown, the present invention can improve the drawbacks that the conventional heat pipe does not own sufficient flexibility in arrangement and installation. For example, if a display card with plural heat sources 41, 42 employs the heat pipe, then, through the metal pipe 10 which has the indentation portion 21 to form the sealing surface 30 so as to divide into the first section a and the second section b for respectively proceeding the heat absorption/exothermic cycle, and also has a heat sink 50 at the end portions thereof for increasing the heat dispersing effect, the two heat sources 41, 42 can jointly employ one identical metal pipe 10 but still can achieve the effect provided by two hear pipes. This can be carried out on, for example, the Southbridge and Northbridge chipsets, or CPU, etc.

In the aforesaid, the present invention provides a heat pipe structure with sectional heat conducting capability, in which through a sealing surface 30 formed by an indentation portion 21 on the metal pipe 10, the heat pipe can be divided into different heat dispersing sections a, b, so that one signal heat pipe can have two sections of heat dispersing cycles so as to accelerate the backflow speed of the working liquid. Therefore, except improving the arrangement flexibility and heat dispersing effect, the processing procedure can be simplified and the cost also can be reduced.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat pipe structure with sectional heat conducting capability comprising a hollow metal pipe and a working liquid, in the hollow metal pipe, having a heat absorption/exothermic cycle for achieving a heat dispersing effect, characterized in that:
at least one pressed section is located between the ends of the metal pipe, and the pressed section further has, relative to the pipe, an indentation portion to contact with the sidewall of the metal pipe so as to form a sealing surface on the metal pipe such the metal pipe is divided into at least two sections which respectively have a heat absorption/exothermic cycle.

2. The heat pipe structure with sectional heat conducting capability as claimed in claim 1, wherein the sealing surface is formed by contacting two indentation portions at a corresponding position.

3. The heat pipe structure with sectional heat conducting capability as claimed in claim 1, wherein the metal pipe has a rectangular section.

4. The heat pipe structure with sectional heat conducting capability as claimed in claim 1, wherein the metal pipe has a circular section.

5. The heat pipe structure with sectional heat conducting capability as claimed in claim 1, wherein the metal pipe has at least one bending point.
